(19) United States
(12) Patent Application Publication
(10) Pub. No.: US 2005/0001266 A1
(43) Pub. Date: Jan. 6, 2005

(54) Recess type transistor and method of fabricating the same

(76) Inventor: Ji-Young Kim, Gyeonggi-do (KR)

Correspondence Address: MARGER JOHNSON & McCOLLOM, P.C., 1030 S.W. Morrison Street, Portland, OR, 97205, US

(21) Appl. No.: 10/871,193

(22) Filed: Jun. 18, 2004

(30) Foreign Application Priority Data
Jul. 2, 2003 (KR) 2003-44502

(51) Int. Cl. H01L 21/336; H01L 29/94

(52) U.S. Cl. 257/330; 438/259; 257/619; 438/459

(57) ABSTRACT

Embodiments of the invention include a semiconductor substrate having an active region defined by a device isolation film, at least one trench formed in the active region, and a growth silicon layer formed along an internal face of the trench. The transistor also includes a first impurity region of first conductive type that is formed on a boundary region between the growth silicon layer and its opposite active region, and a gate insulation layer formed on upper parts of the growth silicon layer within the trench and the active region. Embodiments include a gate electrode having an upper part and a lower part, the gate electrode formed on the gate insulation layer, the upper part wider than the lower part, the upper part partially overlapping the growth silicon layer; and a second impurity region of second conductive type formed in the active region at both sides of the gate electrode.

### CROSS REFERENCE TO RELATED APPLICATIONS

The application claims priority from Korean Patent Application 2003-44502, filed on Jul. 2, 2003, the contents of which are hereby incorporated by reference in their entirety for all purposes.

### BACKGROUND OF THE INVENTION

1. Field of the Invention

This disclosure relates to a transistor of a semiconductor memory device, and more particularly, to a recess type transistor having a trench channel, and a method of fabricating the same.

2. Description of the Related Art

The current trend to achieve highly integrated semiconductor devices brings about a gradual miniaturization of MOS (Metal-Oxide Semiconductor) transistors. In order to increase an operating speed and a current driving capability of the device, a channel length is reduced into the sub-micron level.

The gradual reduction of the channel length causes a depletion region of source and drain to invade the interior of the channel, reducing an effective length of the channel and a threshold voltage. Thus, a short channel effect may cause a loss of a gate control function from a MOS (Metal-Oxide Semiconductor) transistor.

In order to cope with the short channel effect, a dopant of opposite conductive type is ion implanted into a lower part of the channel region, together with a shallow junction, but a high electric field is applied to the semiconductor device to generate a hot carrier therein. The hot carrier causes a collision ionization when the hot carrier invades an oxide layer, causing a degradation of the oxide layer and a defect in the device.

In order to reduce the hot carrier effect, most conventional transistor fabricating processes employ a lightly doped drain (LDD) structure, which forms a buffer region of low density implantation between a gate region and a drain region having a high-density implantation.

However, the channel length is further shortened by the requirement for a highly-integrated semiconductor device, thus a transistor having a LDD structure is limited in how far it can reduce the short channel and the hot carrier effect. Furthermore, a punch-through effect is also present due to impurities in the source and drain that diffuse toward a side face during the operation of transistor.

In one method to resolve this problem and reduce a size of memory cell based on the high-density packing formed in a semiconductor substrate, a necessity for the development of transistor based on a recess or groove type in a gate channel length per unit area becomes powerful, rather than a planner type.

The recess type transistor helps to achieve highly integrated semiconductor devices by forming the trench in a region where a channel will be formed, so as to increase an effective channel length, and by improving the punch-through of source and drain so as to actually widen a distance between the source and drain.

However, such a recess type transistor causes many problems during the manufacturing process and in particular, during a trench device isolation process. These problems are caused almost for the same reasons why a size of gate electrode and an interval between gate lines become narrower as design rule become smaller.

The conventional recess type transistor and its fabricating method will be described below, with reference to FIGS. 1 to 2.

FIGS. 1a to 1i are cross-sectional diagrams illustrating a method of fabricating a recess type transistor according to the conventional art, and FIGS. 2a to 2i are cross-sectional diagrams taken along the I˜I′ line referred to in FIG. 1a to 1i. For convenience, the I˜I′ line is shown only in FIG. 1a.

As shown in FIGS. 1a and 2a, a pad oxide layer 14 and a mask layer 16 are accumulated in sequence on a semiconductor substrate 12 in which an active region is defined by a device isolation film 10, and a photoresist is deposited on the mask layer 16, and a photoresist pattern 18 is formed by using a photolithography process.

As shown in FIGS. 1b and 2b, a portion of the mask layer 16 is etched so as to expose the pad oxide layer 14 by using the photoresist pattern (18 of FIG. 1a) as an etch mask. Further, the photoresist pattern 18 is removed.

As shown in FIGS. 1c and 2c, the pad oxide layer 14 is partially removed so as to expose the semiconductor substrate 12 by using the mask layer 16 as an etch mask.

As shown in FIGS. 1d and 2d, a surface of the semiconductor substrate 12 is etched to a determined depth through use of the mask layer 16 and the pad oxide layer 14 as an etch mask layer, to thus form a trench 20. Since the depth profile of the trench 20 may become different according to an open critical dimension (CD) thereof, the trench should be formed to have a determined open CD. Further, the etching process of the pad oxide layer 14 and the formation process of the trench 20 are performed in situ, within one reaction chamber.

The mask layer 16 serves as a sacrifice layer and is removed in the formation process of the trench 20, and the pad oxide layer 14 serves as an etch stop layer in the etching process of the mask layer 16.

As shown in FIGS. 1e and 2e, after removing the mask layer 16, a sidewall of the trench 20 is removed by an isotropic etching method (such as a chemical dry etching (CDE) process) to define source and drain regions. At this time, the isotropic etching method is performed to etch the surface of the semiconductor substrate 12 within the trench 20, thus not only the sidewall of trench 20 but also the depth of the trench 20 may be increased.

Next, a dopant is ion implanted in the semiconductor substrate 12 corresponding to a lower part and sidewall portion of the trench 20, thus forming a first impurity region 22. The first impurity region 22 serves the role of a channel adjusting impurity doping region in order to cope with the short channel effect.

With reference to FIGS. 1f and 2f, the pad oxide layer 14 remaining on the semiconductor substrate 12 is removed, and a gate insulation layer 26 is formed on an entire face of the semiconductor substrate 12 including the trench 20.

With reference to FIGS. 1g and 2g, a gate electrode 28 formed of polysilicon material, a metal silicide layer 30, and a gate insulation layer 32 are accumulated on the semiconductor substrate on which the gate insulation layer 26 is formed.

As shown in FIG. 1h and FIG. 2h, a gate upper insulation layer 32, a metal silicide layer 30, and a gate electrode 28, which correspond to the source and drain regions and to a portion of the trench, are sequentially removed, to thus form a gate stack 34. At this time, a CD of the gate stack 34 is smaller than an open CD of the trench 20 so as to be positioned within the interior of the trench 20.

As shown in FIGS. 1i and 2i, a spacer 36 is formed in a gate sidewall, and centering on the gate stack 34, a dopant is ion implanted in the source and drain regions, thus forming a second impurity region 38. The second impurity region 38 is formed by doping an impurity with a conductivity type opposite to that of the first impurity region 22.

Through the above processes, the recess type transistor based on the conventional art is obtained, and then, the gate insulation layer 26 is removed from the source and drain regions. Next, a bitline contact and storage node contact can be formed on the source and drain regions.

However, the recess-type transistor based on the conventional art is susceptible to the following problems.

First, if the open CD of trench is greater than the CD of gate stack, a gate electrode of polysilicon material formed within the trench is excessively etched in forming the gate stack, forming a depression at the edge of the trench. Thus, since it is difficult to guarantee an etching reproducibility, there is a limitation that the CD of the gate stack should be greater than the open CD of trench.

Secondly, if the CD of the gate stack is greater than the CD of the trench, a bottom CD of a self aligned contact (SAC) should be formed smaller in a subsequent process. Thus, a defect in a bitline contact or a storage node contact may be caused.

Third, if a thickness of a gate electrode made of polysilicon material formed on the gate insulation layer is small, the gate electrode formed in the trench is prone to curvature due to a stepped coverage of the trench, thus causing a split on the metal silicide layer formed on the generated curvature.

Embodiments of the invention address these and other disadvantages of the conventional art.

### SUMMARY OF THE INVENTION

Embodiments of the invention provide a recess type transistor and a method of fabricating the same, which is capable of getting rid of a limitation to a CD of gate stack greater than an open CD of trench. Embodiments of the invention provide a recess type transistor and a fabricating method thereof, which increases a bottom CD of a self aligned contact (SAC) by reducing a CD of gate stack smaller than an open CD of trench, and prevents a defect of bitline contact and storage node contact. Still other embodiments of the invention also provide a recess type transistor and a fabricating method thereof, which reduces a thickness of gate electrode formed in an opening part and flattens the gate electrode formed in the opening part so as to prevent a split of metal silicide layer formed on the gate electrode.

### BRIEF DESCRIPTION OF THE DRAWINGS

The above and other features of exemplary embodiments of the invention will become readily apparent from the description that follows, with reference to the attached drawings.

FIGS. 1a through 1i are cross-sectional diagrams illustrating a fabricating process of a recess type transistor according to the conventional art.

FIGS. 2a through 2i are cross-sectional diagrams taken along the I˜I′ line shown in FIG. 1a.

FIG. 3 is a cross-sectional diagram of a recess type transistor according to some embodiments of the invention.

FIGS. 4a through 4j are cross-sectional diagrams illustrating a fabrication process for the recess type transistor of FIG. 3.

FIGS. 5a through 5j are cross-sectional diagrams corresponding to FIGS. 4a through 4j, respectively, but taken along the II˜II′ line shown in FIG. 3.

FIG. 6 is a cross-sectional diagram illustrating a recess type transistor according to other embodiments of the invention.

FIGS. 7a through 7j are cross-sectional diagrams illustrating a fabrication process for the recess type transistor of FIG. 6.

FIGS. 8a through 8j are cross-sectional diagrams corresponding to FIGS. 7a through 7j, respectively, but taken along the III˜III′ line referred to FIG. 6.

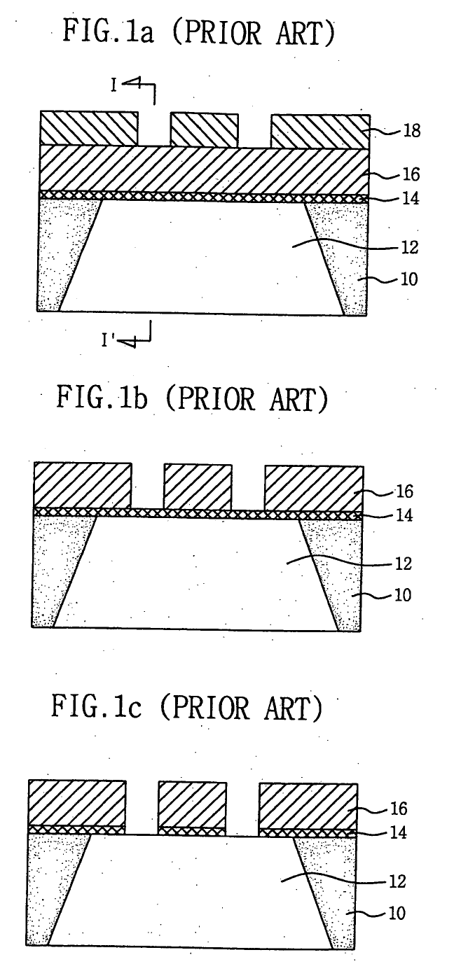

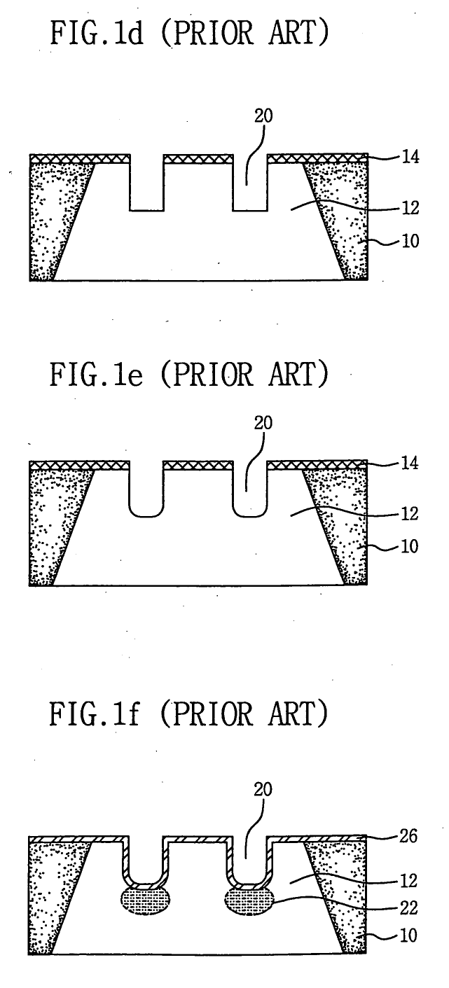

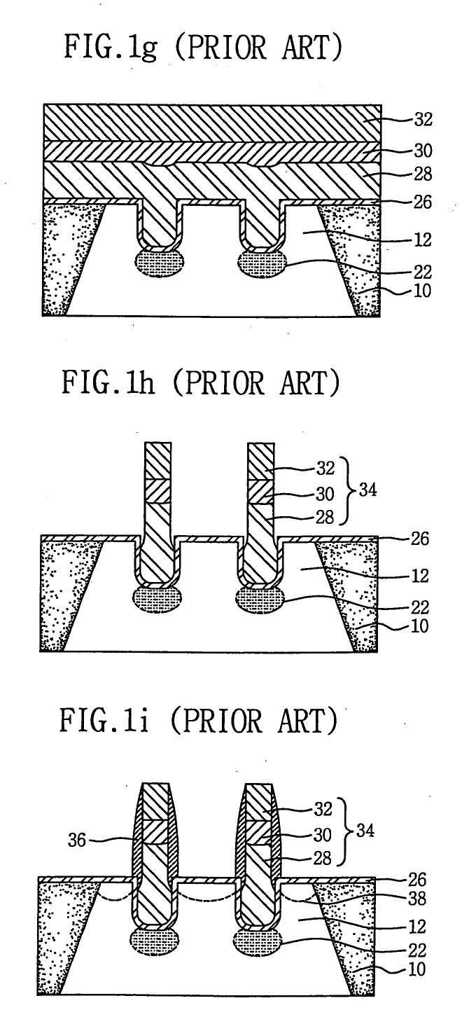

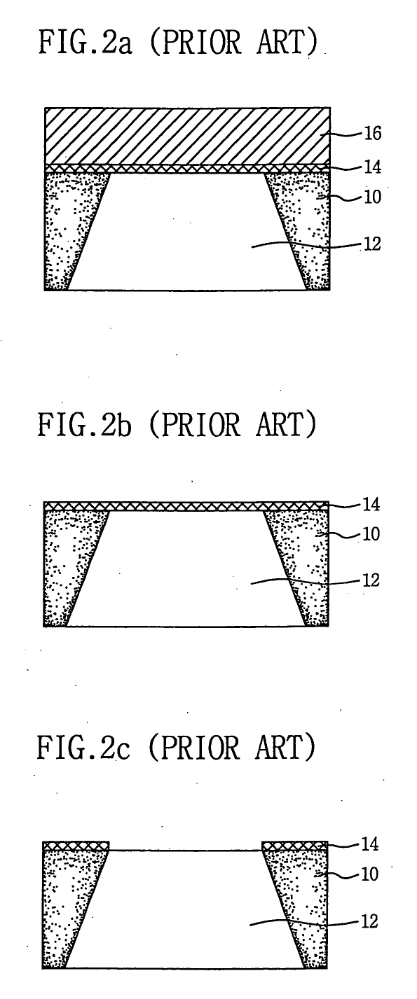

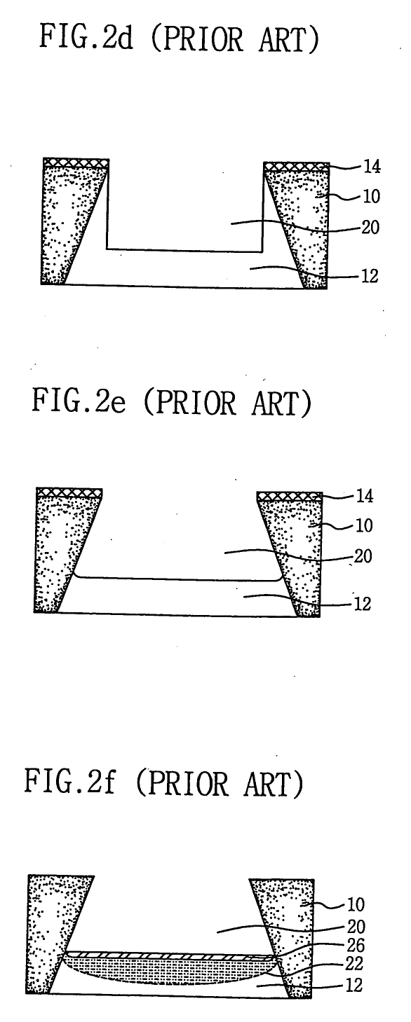

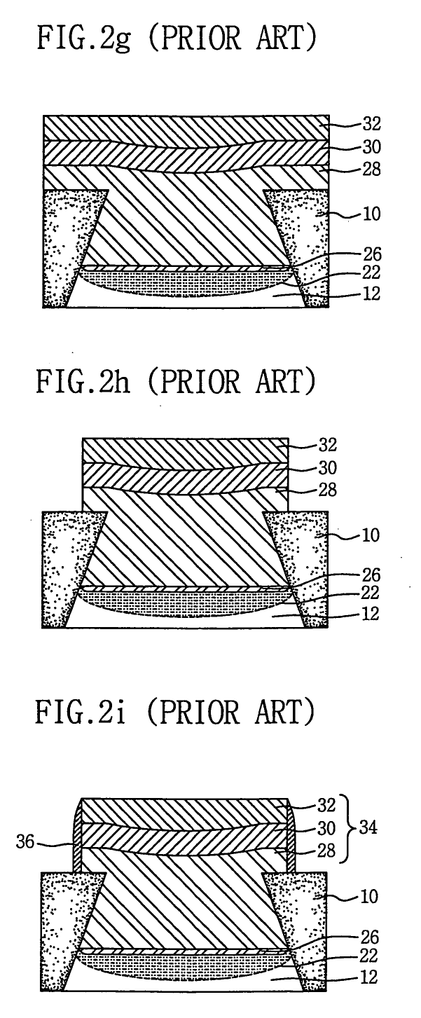

### DETAILED DESCRIPTION OF THE INVENTION

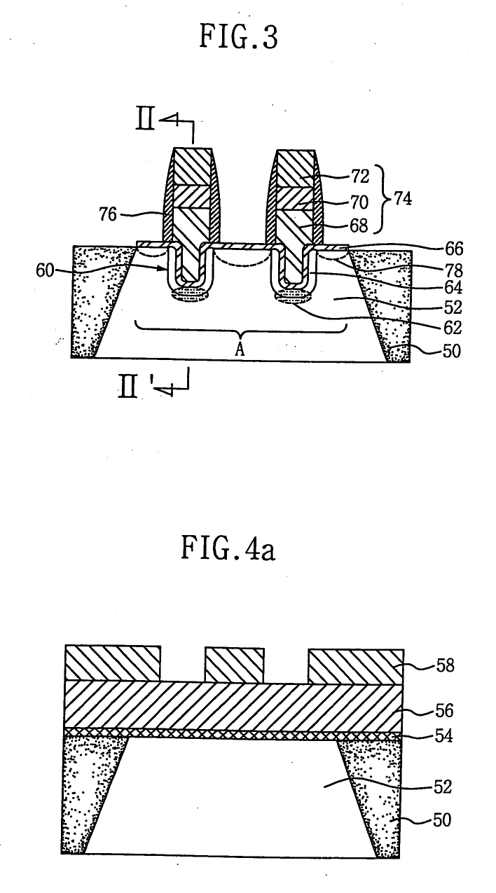

According to example embodiments of the invention, the structure of a recess type transistor and a fabricating method thereof will be described with reference to FIGS. 3 to 8, in which like components having like functions have been provided with like reference symbols and numerals.

It will be understood by those skilled in the art that the invention may be practiced in numerous ways and is not limited to the following described embodiments. The following various embodiments are exemplary in nature.

FIG. 3 is a cross-sectional diagram illustrating a recess type transistor according to some embodiments of the invention. Referring to FIG. 3, an active region A is defined by a device isolation film 50, and two trenches 60 are formed in the active region. Herewith, the two trenches 60 are provided to be formed together on the same active region A, and according to some cases, the number of trenches may increase or decrease. Under the design rule of deep sub-micron meter, an open CD of the trench 60 may be about 700 Å to 900 Å, and a depth of the trench 60 may be about 1000 Å to 1500 Å. Furthermore, a growth silicon layer 64 is formed along the surface of the semiconductor substrate 52 in the interior of the two trenches 60, wherein the growth silicon layer 64 has a thickness of about 100 Å to 300 Å and is used as a U-shaped channel layer within the trench 60 by reducing the open CD and the depth of the trench 60, and an end thereof is partially projected toward an upper side of the trench 60.

Further, a first impurity region 62 of first conductivity type is formed on a boundary region between the growth silicon layer 64 formed in a lower part of the trench 60 and the active region A opposite to the growth silicon layer 64. The first impurity region 62 is a channel adjusting impurity doping region that prevents punch-through, and may contain a donor impurity such as phosphorous (P) or arsenic (As) for a PMOS case, or it may contain an acceptor impurity such as boron (B) or BF₂ for an NMOS case. The first impurity region 62 may be formed along an entire region of the growth silicon layer 64.

A gate insulation layer 66 is formed on an upper part of the growth silicon layer 64 within the trench 60 and on an upper part of the active region A. Herewith, the gate insulation layer 66 is formed of silicon oxide layer or silicon nitride layer to about 30 Å to 80 Å. Also, the gate insulation layer 66 formed on the active region A is removed except for the portion of the gate insulation layer 66 corresponding to the trench 60 in order for a direct connection with a bitline contact and a storage node contact. On the base of an upper part of the gate insulation layer 60 formed on the active region A, a gate electrode 68 is formed that is T-shaped. The upper part of the T-shaped gate electrode 68 partially overlaps the growth silicon layer 64 provided in the sidewall of the trench 60.

The gate electrode 68 is made of polycrystalline silicon containing a conductive impurity, and a thickness thereof is reduced as compared with a conventional case, through a buried opening part, wherein the opening part has a reduced CD through use of the growth silicon 64 provided within the trench 60. The gate electrode 68 overlaps the growth silicon layer 64 formed in the sidewall of the trench 60, thus a CD of the gate electrode 68 is smaller than the open CD of the trench 60.

A metal silicide layer 70 and a gate upper insulation layer 72 are accumulated on the gate electrode 68, thus providing a gate stack 74. A spacer 76 is formed a sidewall of the gate stack 74. Furthermore, a second impurity region 78 of second conductive type is formed in both sides of the gate electrode 68 in the active region A, wherein the second impurity region 78 involves an acceptor or donor impurity of a conductivity type opposite to the first conductive impurity doped in the first impurity region 62.

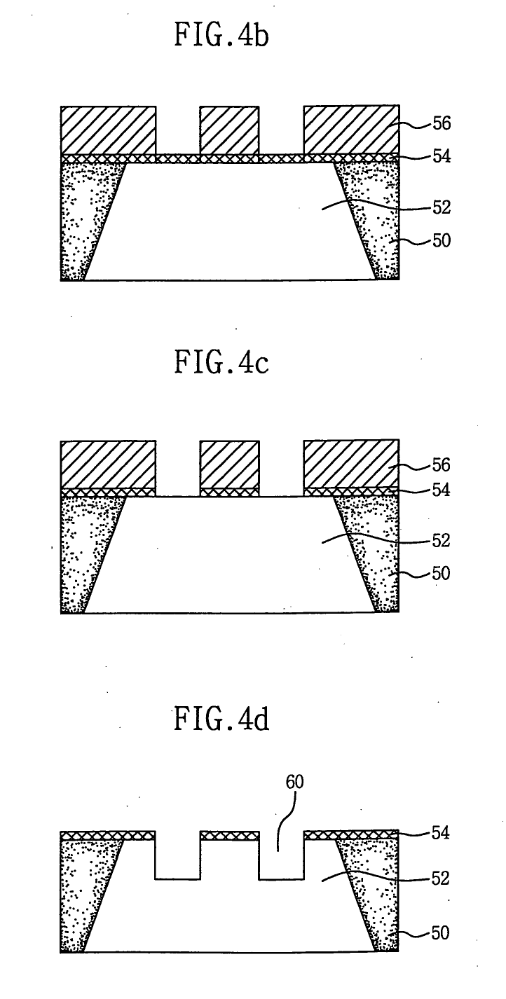

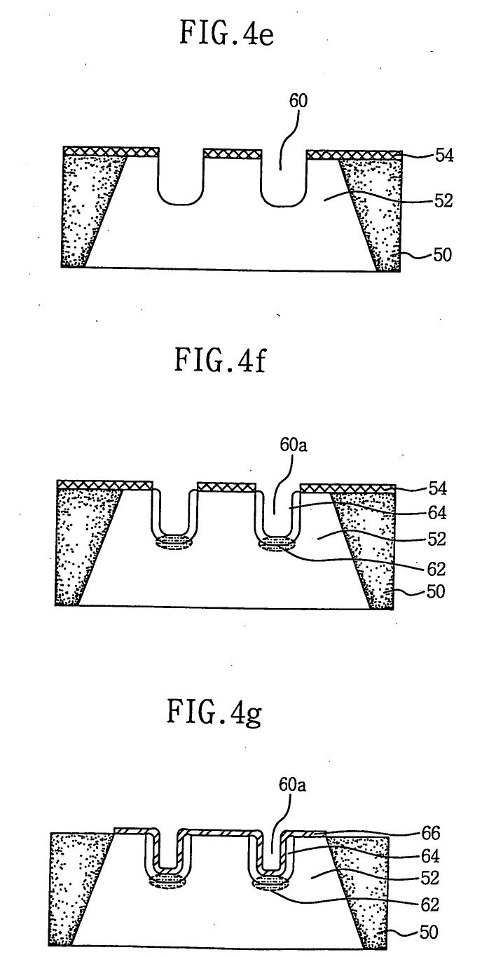

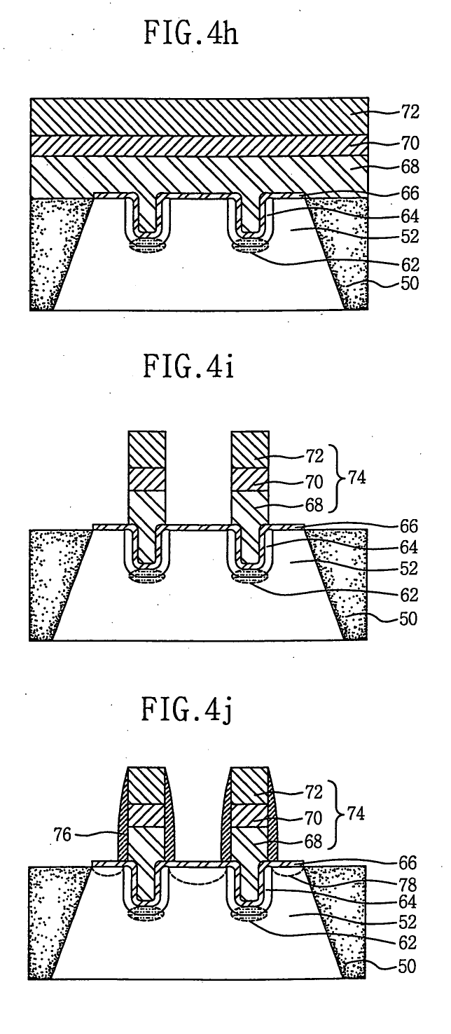

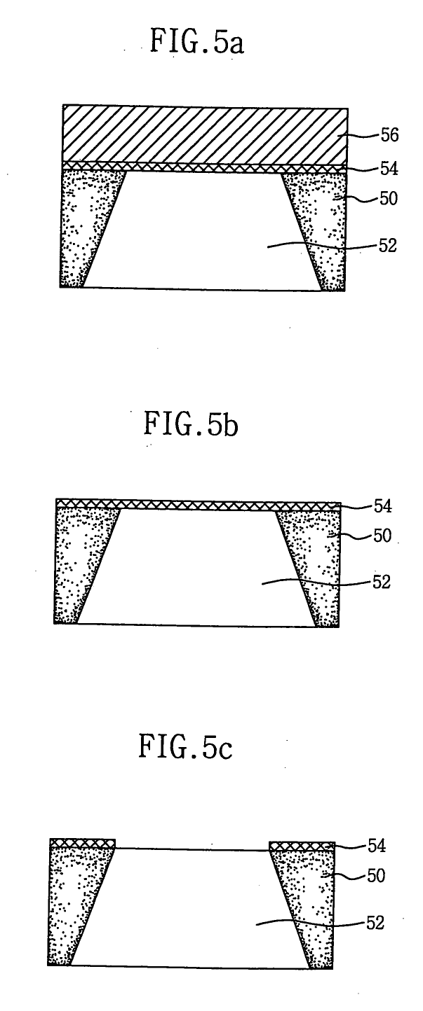

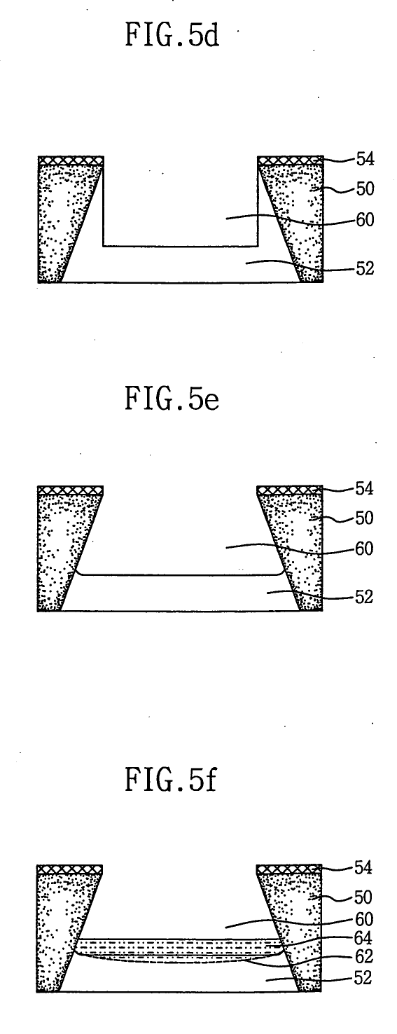

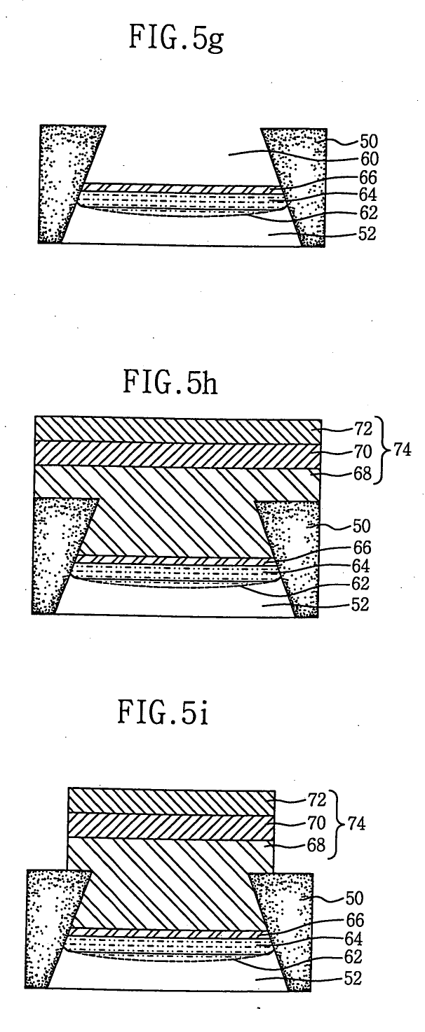

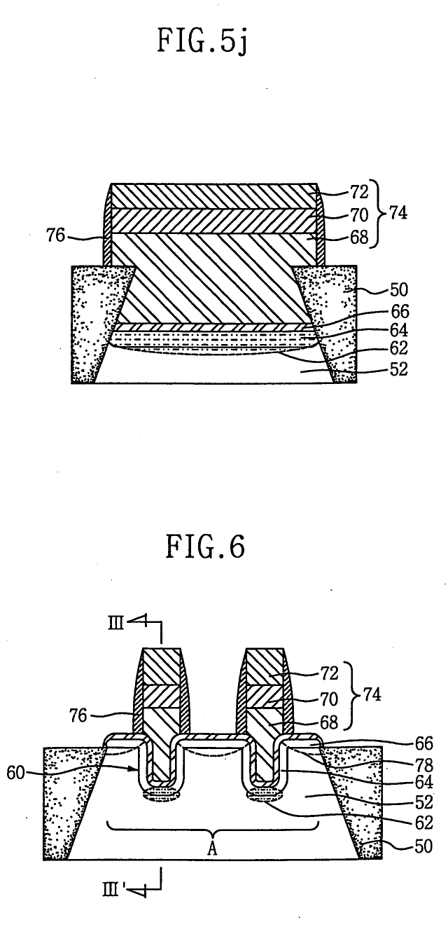

A sequential process of fabricating the recess type transistor shown in FIG. 3 is described below with reference to FIGS. 4a through 4j and FIGS. 5a through 5j.

FIGS. 4a through 4j are cross-sectional diagrams illustrating a recess type transistor fabricating method according to some embodiments of the invention. FIGS. 5a through 5j are cross-sectional diagrams corresponding to FIGS. 4a through 4j, respectively, but taken along the II˜II′ line shown in FIG. 3.

As shown in FIGS. 4a and 5a, a pad oxide layer 54 and a mask layer 56 are sequentially accumulated on the semiconductor substrate 52 on which the device isolation film 50 is formed, and a photosensitive layer, e.g., photoresist, is deposited on the mask layer 56, to form a photoresist pattern 58 through a photolithography process.

The pad oxide layer 54 is formed to a thickness of about 300 Å to 1000 Å through an MTO (Medium Temperature Oxide) method, and the mask layer 56 is formed to a thickness of about 1000 Å to 1500 Å through a chemical vapor deposition (CVD) method by using polysilicon.

As shown in FIGS. 4b and 5b, a portion of the mask layer 56 is etched so as to expose the pad oxide layer 54 by using the photoresist pattern 58 as an etch mask, and then the photoresist pattern 58 is removed.

As shown in FIGS. 4c and 5c, the pad oxide layer 54 is partially removed to expose the semiconductor substrate 52, by using the mask layer 56 as an etch mask. Herewith, the etching process of the pad oxide layer 54 is called a BT (Break-Through) process and the BT process is performed through a dry etching method.

As shown in FIGS. 4d and 5d, the surface of the semiconductor substrate 52 is etched by a determined depth by using the mask layer 56 and the pad oxide layer 54 as an etch mask layer, to thus form a trench 60. Herewith, the process of etching the semiconductor substrate 52 and forming the trench 60 is called an ME (Main Etching) process, and the BT and ME processes are performed in situ, in one reaction chamber. At this time, the mask layer 56 is a sacrifice layer and is removed in the ME process, and the pad oxide layer 54 serves as an etching stop layer in the etching of the mask layer 56.

As shown in FIGS. 4e and 5e, a sidewall of the trench 60 remaining in forming the trench 60 is removed by using an isotropic etching process, to define between source and drain regions. The isotropic etching process employs a CDE (Chemical Dry Etching) method. The isotropic etching process performs an isotropic etching for the surface of the semiconductor substrate 52 provided within the trench 60, thus, not only a sidewall of the trench 60 but also a depth of the trench 60 can be further increased, and the trench 60 may be formed roundly.

At this time, the trench 60 is formed to have an open CD of about 700 Å to 900 Å and a depth of about 1000 Å through 1500 Å. Further, an edge portion of the semiconductor substrate 52 adjacent to the device isolation film 50 in an internal wall of the trench 60 is not etched, but remains rounded.

After the process of forming the trench 60 or dividing the source and drain regions, and in order to remove a polymer component generated in an etching process of the semiconductor substrate 52 and the mask layer 56, the semiconductor substrate 52 may be subjected to an ashing or cleaning process. Also, since the surface of the semiconductor substrate 52 may be damaged by etching in the ME process and the isotropic etching process, a thermal oxide process is additionally executed in order to eliminate the damage. At this time, an oxide layer (not shown) may be generated on the surface of the semiconductor substrate 52 within the trench 60 by the thermal oxide process. A process of removing the oxide layer generated by the thermal oxide process on the surface of the semiconductor substrate 52 within the trench 60 may also be performed.

As shown in FIGS. 4f and 5f, the growth silicon layer 64 is formed through a selective epitaxial growth (SEG) method on the semiconductor substrate 52 within the trench 60. At this time, the growth silicon layer 64 can be formed to selectively have a thickness of about 100 Å to 300 Å only in the interior of trench 60 exposed by the pad oxide layer 54.

Specifically, since the growth silicon layer 64 is formed small on the semiconductor substrate 52 neighboring to the device isolation film 50 within the trench 60, the growth silicon is flat formed on the surface of the semiconductor substrate 52 whose portion neighboring to the device isolation film is round-shaped through the isotropic etching process. Further, the growth silicon layer 64 formed at the edge of the trench upper part is formed with a given round shape adjacent to the pad oxide layer 54.

Thus, the growth silicon layer 64 is formed with a first opening part 60a of a trench shape within the trench 60. Then, the first opening part 60a is buried and the gate electrode 68 is formed to partially overlap the growth silicon layer 64.

Together with the formation of the growth silicon layer 64, the first impurity region 62 of low density may be formed by using a mixed gas containing an acceptor impurity such as B or BF₂ or a donor impurity such as P or As. Alternatively, the first impurity region 62 is formed through an ion implantation method in the growth silicon layer 64 formed in a lower part or sidewall of the trench 60, after forming the growth silicon layer 64 on the semiconductor substrate 52 provided within the trench 60.

Next, the pad oxide layer 54 is removed from the semiconductor substrate 52.

As shown in FIGS. 4g and 5g, the gate insulation layer 66 is formed on the growth silicon layer 64 and the semiconductor substrate 52. At this time, the gate insulation layer 66 is formed to a thickness of about 30 through 80 Å through a wet method.

With reference to FIGS. 4h and 5h, the gate electrode 68 of polysilicon material is formed on the semiconductor substrate 52 on which the gate insulation layer 66 is formed, and the metal silicide layer 70 is then formed on the gate electrode 68, and subsequently, the gate upper insulation layer 72 is formed on the metal silicide layer 70. An open CD of the first opening part 60a formed within the trench 60 through the growth silicon layer 64 is smaller than an open CD of a conventional trench thus the gate electrode 68 is formed with a smaller thickness than a conventional case, so as to form the flat gate electrode 68.

Further, if a curvature is caused in the gate electrode 68 provided with an upper side of the opening part due to an stepped coverage of the opening part by reducing a thickness of the gate electrode 68, the gate electrode 68 is flattened by using a chemical mechanic polishing (CMP) method, and the metal silicide layer 70 on the gate electrode 68 is flattened, thereby a split on the metal silicide layer can be prevented.

The metal silicide layer 70 may be formed of, for instance, WSiₓ, TaSi₂, or MoSi₂.

Furthermore, on the metal silicide layer 70, the gate upper insulation layer 72 can be formed of any one of SiO₂, SiN and SiON.

As shown in FIGS. 4i and 5i, the gate stack 74 is obtained by forming a photoresist pattern on the gate upper insulation layer 72 shown in FIGS. 4h and 5h and by performing a photolithography process. That is, the gate stack 74 shown in FIGS. 4i and 5i is formed by sequentially etching the gate upper insulation layer 72, the metal silicide layer 70, and the gate electrode 68 exposed through use of the photoresist pattern. Herewith, the gate stack 74 is formed at a portion except an upper part of the source and drain region and except an upper side part of the trench 60; and a width of the gate stack 74 overlaps with an upper part of the growth silicon layer 64.

Herewith, the gate stack 74 partially overlaps the growth silicon layer 64 formed in a sidewall of the trench 60, thus the gate electrode 68 provided within the opening part is not etched in an etching process of the gate electrode 68. That is, a defect in an etching process can be prevented.

In addition, a CD of the gate stack 74 can be smaller than an open CD of the trench 60, thus a contact defect of bitline contact and storage node can be prevented by increasing a bottom CD of the self aligned contact (SAC).

Referring to FIGS. 4j and 5j, an insulation layer may be formed on the semiconductor substrate 52 on which the gate stack 74 is formed, and a spacer 76 may be formed on a sidewall of the gate stack 74 by using a partial etching method.

The spacer 76 can be formed of any one of SiO₂, the SiN series, and SiON.

Then, the second impurity region 78 may be formed in the source and drain regions of the semiconductor substrate at both sides of the gate stack 74 through an ion implantation method, and the recess type transistor may be obtained by removing the gate insulation layer 66 formed on the source and drain regions of the semiconductor substrate 52.

The second impurity region 78 may be formed by ion implanting an acceptor or donor impurity in the semiconductor substrate 52 of the active region A through use of the gate stack 74 and the spacer as a mask.

Alternatively, the second impurity region 78 having a low density may be formed on the active region A before the process of forming the pad oxide layer 54 and the mask layer 56. The second impurity region of low density is used as drain and source regions. The drain region is electrically connected to a bitline through a direct contact (DC), and the source region is electrically connected to a storage node through a buried contact (BC). In the meantime, the drain and source regions can be changed to an LDD type based on a double ion implantation.

Therefore, in the recess-type transistor fabricating method based on the above embodiments of the invention, the growth silicon layer 64 is formed within the trench 60, and the gate stack 74 is formed to partially overlap the growth silicon layer 64, stabilizing the etching process for the gate stack 74 and substantially reducing a contact defect in bitline contacts and storage nodes by increasing a bottom CD of the SAC.

FIG. 6 is a cross sectional diagram illustrating a recess type transistor according to other embodiments of the invention. Referring to FIG. 6, the active region A is defined by the device isolation film 50 formed on the semiconductor substrate 52, and two trenches 60 are formed in the active region A. Herewith, the two trenches 60 are provided to be formed together on the same active region A, and according to some cases, the number of trenches may increase or decrease. Under the design rule of deep sub-micron meter, an open CD of the trench 60 may be about 700 Å to 900 Å, and a depth of the trench 60 may be about 1000 Å to 1500 Å. Furthermore, the growth silicon layer 64 is formed along the interior of two trenches 60 and the active region A, wherein the growth silicon layer 64 is formed to a thickness of about 100 Å to 300 Å on a face of the semiconductor substrate except for the device isolation film, reducing the open CD of the trench 60 and further increasing the active region A of the semiconductor substrate so as not to change the depth thereof.

Further, a first impurity region 62 of a first conductivity type is formed on a boundary region between the growth silicon layer 64 formed in a lower part of the trench 60 and the active region A opposite to the growth silicon layer 64. The first impurity region 62 is a channel adjusting impurity doping region that prevents punch-through, and it contains a donor impurity such as P or As for a PMOS case, or an acceptor impurity such as B or BF₂ for an NMOS case. The first impurity region 62 may be formed along an entire region of the growth silicon layer 64.

The gate insulation layer 66 is formed along an upper part of the growth silicon layer 64. Herewith, the gate insulation layer 66 is formed to about 30 Å through 80 Å through use of a silicon oxide layer or a silicon nitride layer. The gate insulation layer 66 formed on the active region A is removed, except for the portion of the gate insulation layer 66 corresponding to the trench 60 in order for a direct connection with a bitline contact and a storage node contact. The gate electrode 68 is formed in a T-shape, to partially overlap with the growth silicon layer 64 which is provided on the bottom and sidewall of the trench 60. Herewith, the gate electrode 68 is made of polycrystalline silicon containing a conductive impurity, and a thickness thereof is reduced as compared with a conventional case, through a buried opening part, wherein the opening part has a reduced CD through use of the growth silicon 64 provided within the trench 60.

The gate electrode 68 overlaps the growth silicon layer 64 formed in the sidewall of the trench 60, thus a CD of the gate electrode 68 is smaller than the open CD of the trench 60.

The metal silicide layer 70 and the gate upper insulation layer 72 are accumulated on the gate electrode 68, thus providing the gate stack 74, and on a sidewall of the gate stack 74, the spacer 76 is formed. Furthermore, a second impurity region 78 of a second conductivity type is formed in a boundary region between the growth silicon layer 64 and the active regions A opposite to the growth silicon layer 64.

In the recess type transistor illustrated in FIG. 6, a height of the bitline contact and the storage node contact becomes is greater as compared to the embodiments illustrated in FIG. 3, since the second impurity region 78 is formed on the growth silicon layer 64, which is formed on the semiconductor substrate corresponding to the source and drain regions.

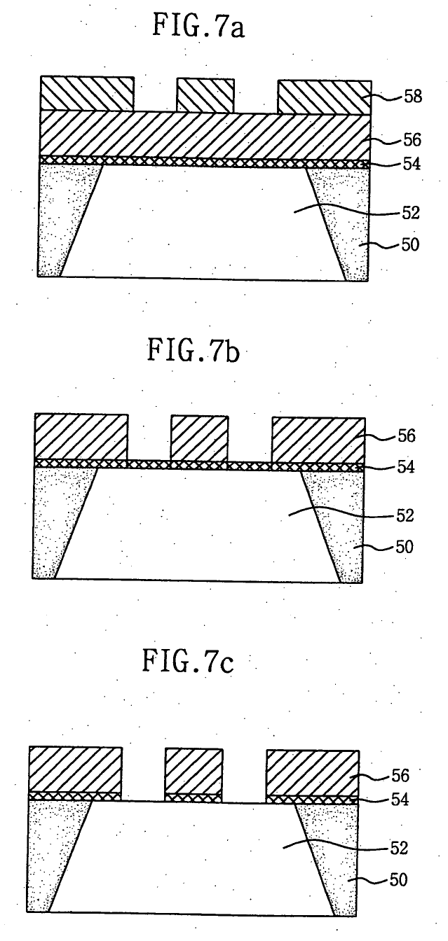

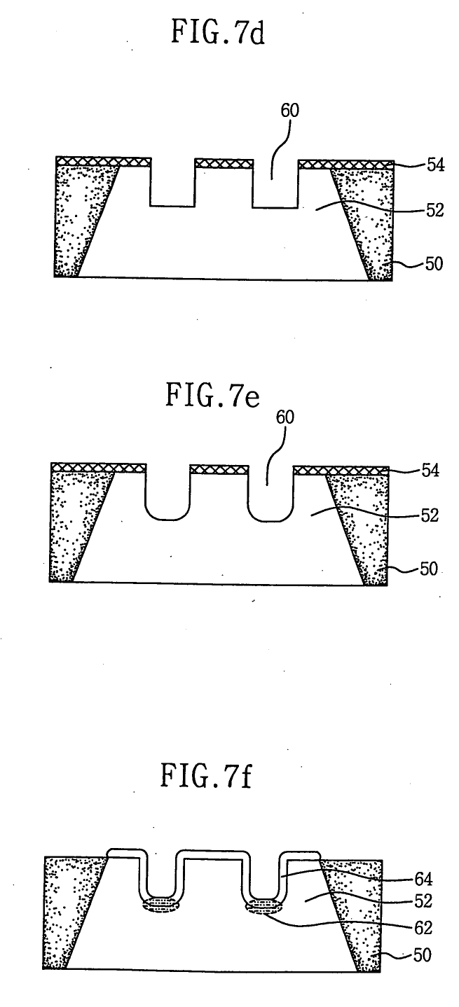

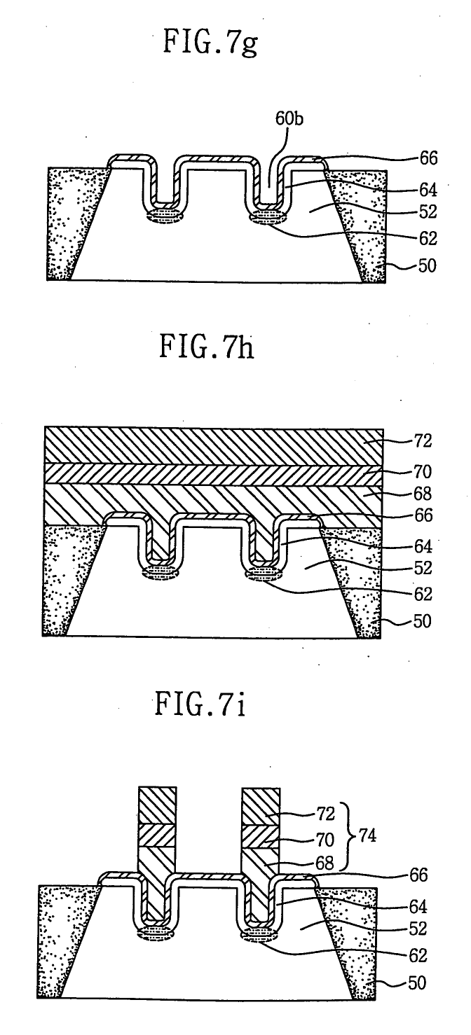

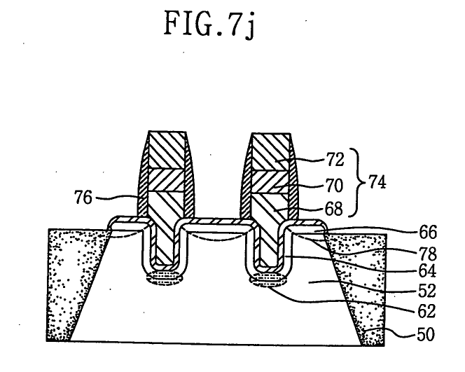

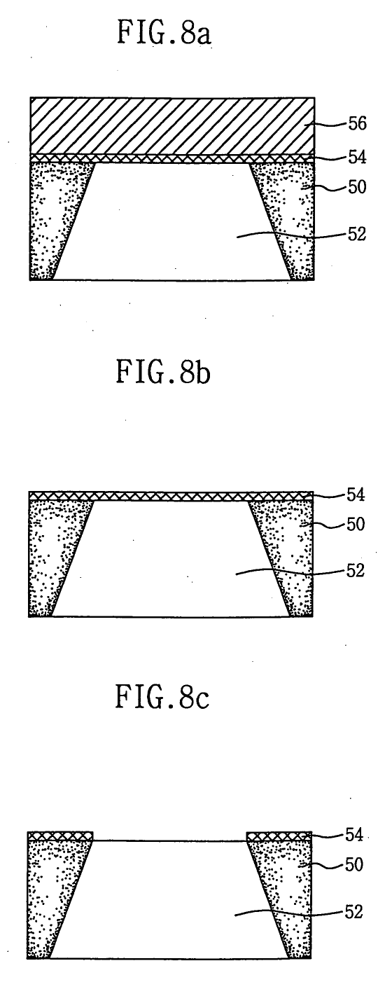

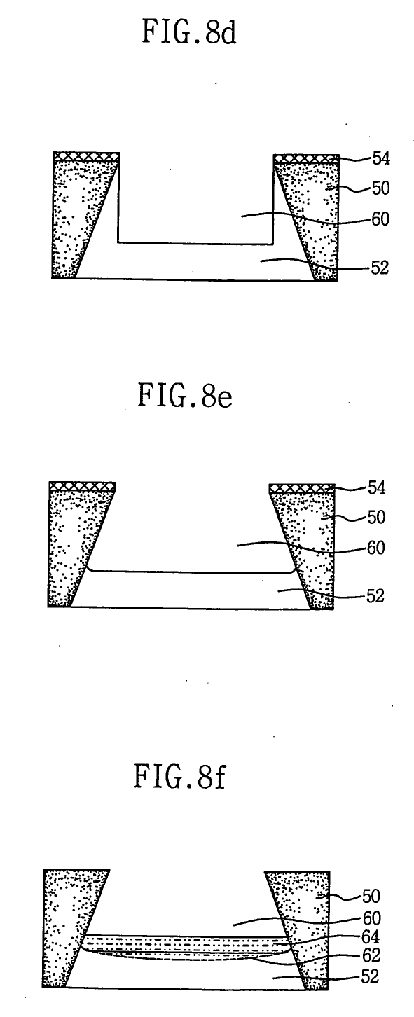

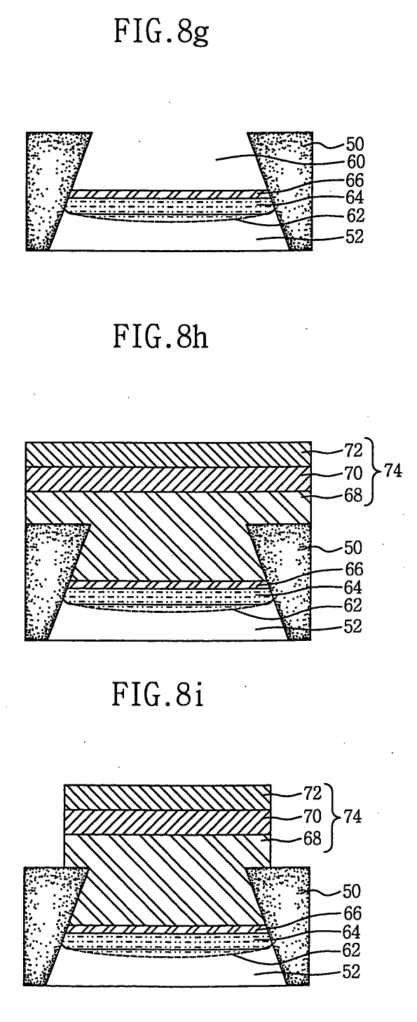

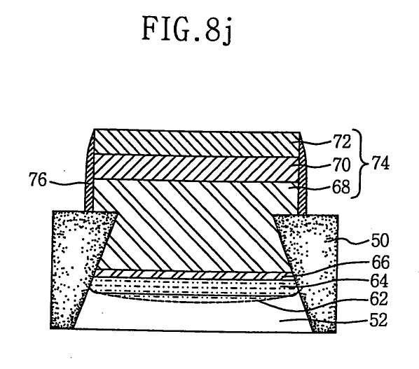

Some processes in fabricating the recess type transistor shown in FIG. 6 are described below with reference to FIGS. 7a through 7j and FIGS. 8a through 8j.

FIGS. 7a through 7j are cross-sectional diagrams illustrating a fabrication process for a recess type transistor according to other embodiments of the invention. FIGS. 8a through 8j are cross-sectional diagrams corresponding to FIGS. 7a through 7j, respectively, but taken along the III˜III′ line referred to FIG. 6.

As shown in FIGS. 7a and 8a, the pad oxide layer 54 and the mask layer 56 are accumulated in sequence on the semiconductor substrate 52 on which the device isolation film 50 is formed, and a photosensitive layer, e.g., photoresist, is deposited on the mask layer 56, to form the photoresist pattern 58 through a photolithography process.

Herewith, the pad oxide layer 54 is formed to have a thickness of about 300 Å to 1000 Å through a MTO (Medium Temperature Oxide) method, and the mask layer 56 is formed to have a thickness of about 1000 Å to 1500 Å through a CVD method by using polysilicon.

As shown in FIGS. 7b and 8b, a portion of the mask layer 56 is etched so as to expose the pad oxide layer 54 by using the photoresist pattern 58 as an etch mask, and then the photoresist pattern 58 is removed.

As shown in FIGS. 7c and 8c, the pad oxide layer 54 is partially removed to expose the semiconductor substrate 52, by using the mask layer 56 as an etch mask.

As shown in FIGS. 7d and 8d, the surface of the semiconductor substrate 52 is etched to a determined depth by using the mask layer 56 and the pad oxide layer 54 as an etch mask layer, thus forming the trench 60. Herewith, the process of forming the trench 60 is performed in situ, within one reaction chamber, together with the process of removing a portion of the pad oxide layer. At this time, the mask layer 56 is removed in the process of forming the trench 60, and the pad oxide layer 54 under the mask layer 56 serves as an etch stop layer.

As shown in FIGS. 7e and 8e, a sidewall of the trench 60 remaining in forming the trench 60 is removed by using an isotropic etching process, to define between source and drain regions. The isotropic etching process employs a CDE (Chemical Dry Etching) method.

The isotropic etching process performs an isotropic etching for the surface of the semiconductor substrate 52 provided within the trench 60, thus, not only a sidewall of the trench 60 but also a depth of the trench 60 can be further increased, and the trench 60 may be rounder in shape since an edge portion of the semiconductor substrate 52 adjacent to the device isolation film 50 that corresponds to an internal wall of the trench 60 is not etched, wherein the trench 60 has an open CD of about 700 Å to 800 Å.

Next, the surface of semiconductor substrate 52 may be damaged by the etching of the semiconductor substrate 52 in the processes of forming the trench 60 and performing the isotropic etching. Thus, in order to remove the damage, a thermal oxide process can be additionally performed. A process of removing an oxide layer (not shown) generated by the thermal oxide process on the surface of the semiconductor substrate 52 within the trench 60 may also be additionally performed.

As shown in FIGS. 7f and 8f, the pad oxide layer 54 is removed from the semiconductor substrate 52, and the growth silicon layer 64 is formed within the trench 60 and on the semiconductor substrate 52 of the active region A involving the source and drain regions through a selective epitaxial growth (SEG) method. The growth silicon layer 64 can be formed to selectively have a thickness of about 100 Å to 300 Å on a face of the semiconductor substrate 52 of the active region A exposed by the device isolation film 50. Also, since the growth silicon layer 64 may be formed relatively small on the semiconductor substrate 52 neighboring to the device isolation film 50 within the trench 60, the growth silicon layer 64 is formed relatively flat on the surface of the semiconductor substrate 52 whose portion neighboring to the device isolation film is round-shaped through the isotropic etching process.

At the same time as the formation of the growth silicon layer 64, the first impurity region 62 of low density may be formed by using a mixed gas containing an acceptor impurity such as B or BF₂ or a donor impurity such as a P or As. Alternatively, the first impurity region 62 may be formed through an ion implantation method in the growth silicon layer 64 formed in a lower part or sidewall of the trench 60.

That is, a second opening part 60b is formed by the interior of the trench 60 and the growth silicon layer 64 formed in a portion of the source and drain regions. Then, the second opening part 60b is buried, and the gate electrode 74 is formed to partially overlap the growth silicon layer 64 formed on the sidewall of the trench 60.

As shown in FIGS. 7g and 8g, the gate insulation layer 66 is formed on the growth silicon layer 64. The gate insulation layer 66 is formed to have a thickness of about 30 Å through 80 Å through a wet method.

With reference to FIGS. 7h and 8h, the gate electrode 68 of polysilicon material is formed on the semiconductor substrate 52 on which the gate insulation layer 66 is formed, and the metal silicide layer 70 is then formed on the gate electrode 68, and subsequently, the gate upper insulation layer 72 is formed on the metal silicide layer 70. An open CD of the second opening part 60b formed within the trench 60 is smaller than an open CD of a conventional trench through use of the growth silicon layer 64. Thus, the gate electrode 68 is formed with a smaller thickness as compared to the conventional one so a flat gate electrode 68 is obtained.

Furthermore, if a curvature is caused in the gate electrode 68 provided with an upper side of the opening part due to an stepped coverage of the opening part by reducing the thickness of the gate electrode 68, the gate electrode 68 is flattened by using the CMP method, and the metal silicide layer 70 on the gate electrode 68 is flattened, thereby a split on the metal silicide layer can be prevented.

The metal silicide layer 70 may be formed of, for instance, WSiₓ, TaSi₂, or MoSi₂. Furthermore, the gate upper insulation layer 72 may be formed of, for instance, SiO₂, SiN, or SiON.

As shown in FIGS. 7i and 8i, the gate upper insulation layer 72, the metal silicide layer 70, and the gate electrode 68, which correspond to the source and drain region and partially correspond to the growth silicon layer 64, are sequentially removed to form the gate stack 74. At this time, the gate stack 74 partially overlaps the growth silicon layer 64 formed on a sidewall of the trench 60. Thus, the gate electrode 68 provided within the second opening part 60b is not etched in an etching process of the gate electrode 68 and a defect caused by an etching process can be prevented. In addition, a CD of the gate stack 74 can be smaller than an open CD of the trench 60, thus a contact defect of a bitline contact and a storage node can be prevented by increasing a bottom CD of self aligned contact (SAC).

Referring to FIGS. 7j and 8j, an insulation layer such as SiO₂, SiN series, or SiON is formed on the gate insulation layer 66 on which the gate stack 74 is formed, and the spacer 76 is formed on the sidewall of the gate stack 74 through a partial etching method.

Then, the second impurity region 78 is formed in the source and drain regions of the semiconductor substrate at both sides of the gate stack 74 through an ion implantation method, and the recess type transistor is obtained by removing the gate insulation layer 66 formed on the source and drain regions of the semiconductor substrate 52.

The second impurity region 78 may be formed by ion implanting an acceptor or donor impurity in the semiconductor substrate 52 of the active region A through use of the gate stack 74 and the spacer as a mask.

Therefore, in the recess-type transistor and the fabricating method for the embodiments of the invention described in FIGS. 7 and 8, the growth silicon layer 64 is formed in the active region A of semiconductor substrate 52 involving the trench 60, and the gate electrode 68 is formed to overlap the growth silicon layer 64 within the trench 60, thereby obtaining stability for the etching process for the gate electrode 68 and substantially reducing a contact defect for bitline contacts and storage nodes by increasing a bottom CD of the SAC as compared with the conventional case.

This recess-type transistor and the fabricating method thereof are applicable not only to an NMOS (N-type Metal Oxide Semiconductor) transistor but also to a PMOS (P-type Metal Oxide Semiconductor) transistor, and also can be applied to other transistors such as a CMOSFET (Complementary Metal Oxide Semiconductor Field Effect Transistor).

As was described above, there are many ways to practice the invention. What follows are exemplary, non-limiting descriptions of some embodiments of the invention.

According to some embodiments of the invention, a recess type transistor includes a semiconductor substrate having an active region which is defined by a device isolation film, and at least one trench formed in the active region. The recess type transistor also includes a growth silicon layer formed along an internal face of the trench, a gate insulation layer formed on upper parts of the growth silicon layer within the trench and the active region, and a gate electrode, whose upper horizontal size is greater by a level partially overlapped with the growth silicon layer of trench sidewall than a lower horizontal size thereof, on the basis of an upper part of the gate insulation layer formed on the active region. Furthermore, the transistor includes an impurity region formed in the active region at both sides of the gate electrode.

The trench has an open CD of about 700 Å through 900 Å and a depth of about 1000 Å through 1500 Å. The growth silicon layer has a thickness of about 100 Å through 300 Å, and the gate insulation layer has a thickness of about 30 Å to 80 Å. Further, the recess type transistor further includes a channel adjusting impurity region formed on a boundary region between the growth silicon of trench lower part and the active region opposite to the growth silicon layer. In addition, the recess type transistor further includes a metal silicide layer and a gate upper insulation layer formed on the gate electrode, and also, further includes a spacer formed in both sides of the gate electrode.

According to some embodiments of the invention, a method of fabricating a recess type transistor includes: accumulating a pad oxide layer and a mask layer on a semiconductor substrate on which a device isolation film is formed, and sequentially patterning portions of the mask layer and the pad oxide layer so that the semiconductor substrate is partially exposed. The method includes partially etching an active region of the semiconductor substrate to form a trench, and etching the semiconductor substrate provided in the trench sidewall to define between source and drain regions. The method also includes forming a growth silicon layer within the trench, removing the pad oxide layer formed on the semiconductor substrate, and forming a gate insulation layer on the growth silicon and semiconductor substrate. The method also includes forming a gate electrode, whose upper horizontal size is greater by a level partially overlapped with the growth silicon layer of trench sidewall than a lower horizontal size thereof, on the basis of an upper part of the gate insulation layer formed on the active region, and forming an impurity region in the active region at both sides of the gate electrode.

The pad oxide layer is formed of an MTO (Medium Temperature Oxide) layer, and the mask layer is formed of polysilicon material. The process of patterning the mask layer and the pad oxide layer involves depositing a photoresist on the mask layer, forming a photoresist pattern by using a photolithography process, and anisotropically etching a portion of the mask layer so as to expose the pad oxide layer by using the photoresist pattern as an etch mask. This method also includes anisotropically etching a portion of the pad oxide layer so as to expose the semiconductor substrate by using the photoresist pattern and the mask layer as an etch mask, and removing the photoresist pattern. In forming the trench, the mask layer is removed simultaneously. The process of defining between the source and drain regions employs an isotropic etching method. This method further includes ashing on the semiconductor substrate to remove a polymer component caused by the formation of trench after forming the trench. This method further includes performing a thermal oxide process after forming the trench, and removing an oxide layer generated by the thermal oxide process. This method further includes removing the pad oxide layer after forming the trench. The process of forming the growth silicon layer uses a selective epitaxial growth (SEG) method. On the growth silicon layer, a channel adjusting impurity region involving a conductive impurity opposite to the conductive impurity of the impurity region is formed. The process of forming the gate insulation layer is performed by wet oxidizing the surface of the semiconductor substrate. The gate electrode is formed of polysilicon containing a conductive impurity.

The process of forming the gate electrode further includes forming a gate electrode on the gate insulation layer, accumulating a metal silicide layer and a gate upper insulation layer on the gate electrode, and partially and sequentially etching the gate upper insulation layer, the metal silicide layer and the gate electrode so as to expose the gate insulation layer provided on source and drain regions, thus forming a gate stack. The process further includes forming the impurity region on the semiconductor substrate of the active region before forming the pad oxide layer and the mask layer.

According to some embodiments of the invention, a recess type transistor includes a semiconductor substrate having an active region defined by a device isolation film, at least one trench formed on the semiconductor substrate of the active region, and a growth silicon layer formed along the interior of the trench and the surface of the active region. Also, the recess type transistor includes a gate insulation layer formed on the growth silicon layer, a gate electrode formed to partially overlap the growth silicon layer of the trench interior and sidewall, and an impurity region formed within the growth silicon layer provided with both sides of the gate electrode.

According to some embodiments of the invention, a method of fabricating a recess type transistor includes accumulating a pad oxide layer and a mask layer on a semiconductor substrate on which a device isolation film is formed, and sequentially patterning portions of the mask layer and the pad oxide layer so as to partially expose the semiconductor substrate. The method includes partially etching the active region of the semiconductor substrate to form a trench, and etching the semiconductor substrate provided with a trench sidewall to define between source and drain regions. The method includes removing the pad oxide layer formed on the semiconductor substrate, forming a growth silicon layer on the active region containing the trench, and forming a gate insulation layer on the growth silicon layer. The method includes forming a gate electrode that partially overlaps the growth silicon layer provided on the interior and sidewalls of the trench, and forming an impurity region on the active region on both sides of the gate electrode.

Embodiments of the invention provide a greater margin against a limitation of CD, substantially reduce a contact defect probability, and improve the flatness of the gate electrode.

As described above, the embodiments of the invention provide the following advantages.

First, a trench is formed in the semiconductor substrate, and a growth silicon layer is formed on the surface of semiconductor substrate at a sidewall of the trench, and a gate stack is formed to overlap with the growth silicon layer, thereby removing a conventional restriction that a CD of the gate stack should be greater than an open CD of the trench.

Secondly, a growth silicon layer is formed in the trench, and a gate stack is then formed to overlap the growth silicon layer at an internal wall of the trench, thus a CD of the gate stack becomes smaller than an open CD of the trench, so as to increase a bottom CD of the SAC. Therefore, a probability for a defect occurrence of bitline contact and storage node contact is substantially reduced.

Third, a flattened state of the gate electrode is maintained even though a thickness of the gate electrode is smaller as compared with the conventional case, therefore a split in the metal silicide layer that often occurs in a conventional process of forming the metal silicide layer can be prevented or reduced substantially.

It will be apparent to those skilled in the art that modifications and variations can be made to the above embodiments without deviating from the spirit or scope of the invention. For example, the shapes of the gate stack and the recess or the configuration of film material may be varied. Likewise, equivalent manufacturing processes may be omitted or added. Thus, it is intended that embodiments of the invention cover any such modifications and variations of this invention provided they come within the scope of the appended claims and their equivalents.

1. A recess type transistor, comprising:
a semiconductor substrate having an active region;
at least one trench formed in the active region;
a growth silicon layer formed along an internal surface of the trench;
a gate insulation layer formed on upper parts of the growth silicon layer within the trench and the active region;
a gate electrode having an upper part and a lower part, the gate electrode formed on the gate insulation layer, the upper part wider than the lower part and the upper part partially overlapping the growth silicon layer; and
an impurity region formed in the active region at both sides of the gate electrode.

2. The transistor of claim 1, wherein the at least one trench has an open critical dimension (CD) of about 700 Å through 900 Å.

3. The transistor of claim 1, wherein the at least one trench has a depth of about 1000 Å through 1500 Å.

4. The transistor of claim 1, wherein the growth silicon layer has a thickness of about 100 Å through 500 Å.

5. The transistor of claim 1, wherein the gate insulation layer has a thickness of about 30 Å through 80 Å.

6. The transistor of claim 1, further comprising a channel adjusting impurity region that is formed of impurities with a conductivity type opposite to that of the impurity region, the channel adjusting impurity region formed beneath a lower part of the trench.

7. The transistor of claim 6, the channel adjusting impurity region formed partially within the growth silicon layer.

8. The transistor of claim 6, the channel adjusting impurity region formed entirely within the growth silicon layer.

9. The transistor of claim 6, the impurities comprising acceptor impurities or donor impurities.

10. The transistor of claim 9, the acceptor impurities comprising B or BF₂.

11. The transistor of claim 9, the donor impurities comprising P or As.

12. The transistor of claim 1, further comprising a metal silicide layer and a gate upper insulation layer that are accumulated on the gate electrode.

13. The transistor of claim 1, further comprising spacers formed on both sides of the gate electrode.

14. A method of fabricating a recess type transistor, comprising:
accumulating a pad oxide layer and a mask layer on a semiconductor substrate on which a device isolation film is formed;
sequentially patterning portions of the mask layer and the pad oxide layer to partially expose the semiconductor substrate;
forming a trench by partially etching an active region of the semiconductor substrate;
etching the semiconductor substrate provided in a trench sidewall to define between source and drain regions;
forming a growth silicon layer within the trench;
removing the pad oxide layer formed on the semiconductor substrate;
forming a gate insulation layer on the growth silicon and semiconductor substrate;
forming a gate electrode on the gate insulation layer and having an upper part and a lower part, the upper part wider than the lower part and the upper part partially overlapping the growth silicon layer; and
forming an impurity region in the active region at both sides of the gate electrode.

15. The method of claim 14, wherein forming the pad oxide layer comprises forming a medium temperature oxide (MTO) layer.

16. The method of claim 14, wherein accumulating the mask layer comprises accumulating a polysilicon material.

17. The method of claim 14, wherein patterning portions of the mask layer and the pad oxide layer comprises:
depositing photoresist on the mask layer, and forming a photoresist pattern by using a photolithography process;
anisotropically etching a portion of the mask layer to expose the pad oxide layer by using the photoresist pattern as an etch mask;
anisotropically etching a portion of the pad oxide layer to expose the semiconductor substrate by using the photoresist pattern and the mask layer as an etch mask; and
removing the photoresist pattern.

18. The method of claim 14, wherein forming the trench comprises simultaneously removing the mask layer.

19. The method of claim 14, wherein etching the semiconductor substrate comprises isotropic etching.

20. The method of claim 19, wherein isotropic etching comprises wet etching.

21. The method of claim 14, further comprising ashing or cleaning on the semiconductor substrate after forming the trench or after etching the semiconductor substrate.

22. The method of claim 14, further comprising, after forming the trench:
performing a thermal oxide process; and
removing an oxide layer generated by the thermal oxide process.

23. The method of claim 14, further comprising removing the pad oxide layer after forming the trench.

24. The method of claim 14, wherein forming the growth silicon layer comprises selective epitaxial growth (SEG).

25. The method of claim 24, wherein SEG comprises chemical vapor deposition (CVD).

26. The method of claim 14, further comprising forming, on the growth silicon layer, a channel adjusting impurity region having impurities of a conductivity type opposite to that of the impurity region.

27. The method of claim 26, wherein forming the channel adjusting impurity region comprises forming the channel adjusting impurity process concurrently with forming the growth silicon layer.

28. The method of claim 27, wherein forming the channel adjusting impurity region comprises mixing the impurities in the process of forming the growth silicon layer.

29. The method of claim 26, wherein forming the channel adjusting impurity region occurs after forming the growth silicon layer.

30. The method of claim 29, wherein forming the channel adjusting impurity region comprises ion implanting the impurities in the growth silicon layer.

31. The method of claim 14, wherein forming the gate insulation layer comprises oxidizing a surface of the semiconductor substrate through use of a wetting method.

32. The method of claim 14, wherein forming the gate electrode comprises forming the gate electrode of polysilicon that contains a conductive impurity.

33. The method of claim 14, wherein forming the gate electrode comprises:
forming the gate electrode on the gate insulation layer;
accumulating a metal silicide layer and an upper gate insulation layer on the gate electrode; and
partially etching the upper gate insulation layer, the metal silicide layer, and the gate electrode to expose the gate insulation layer provided on source and drain regions and to form a gate stack.

34. The method of claim 33, further comprising flattening the gate electrode after forming the gate electrode.

35. The method of claim 34, wherein flattening the gate electrode comprises using a chemical mechanical polishing method.

36. The method of claim 33, further comprising forming a spacer on a sidewall of the gate stack.

37. The method of claim 36, wherein forming the spacer comprises:
forming an insulation layer on the gate insulation layer on which the gate stack is formed; and
partially etching the insulation layer through a partial etching method.

38. The method of claim 36, wherein forming the spacer comprises forming the spacer of one selected from the group consisting of SiO₂, SiN and SiON.

39. The method of claim 33, further comprising, after forming the gate stack, removing portions of the gate insulation layer that cover the source and drain regions.

40. The method of claim 14, further comprising, before accumulating the pad oxide layer and the mask layer, forming the impurity region.

41. A recess type transistor, comprising:
a semiconductor substrate having an active region that is defined by a device isolation film;
at least one trench disposed in the semiconductor substrate of the active region;
a growth silicon layer disposed on an interior of the at least one trench and a surface of the active region;
a gate insulation layer disposed on the growth silicon layer;
a gate electrode disposed within the trench, the gate electrode partially overlapping the growth silicon layer that is on a sidewall of the trench; and
an impurity region disposed within the growth silicon layer at both sides of the gate electrode.

42. A method of fabricating a recess type transistor, comprising:
accumulating a pad oxide layer and a mask layer on a semiconductor substrate on which a device isolation film is formed, and sequentially patterning portions of the mask layer and the pad oxide layer so that the semiconductor substrate is partially exposed;
forming a trench by partially etching an active region of the semiconductor substrate;
etching the semiconductor substrate provided in a trench sidewall to define between source and drain regions;
removing the pad oxide layer formed on the semiconductor substrate;
forming a growth silicon layer on a surface of the trench;
forming a gate insulation layer on the growth silicon;
forming a gate electrode within the trench, the gate electrode partially overlapping the growth silicon layer provided on the trench sidewall; and
forming an impurity region in the active region at both sides of the gate electrode.
